(19) United States
(12) Patent Application Publication
(10) Pub. No.: US 2021/0066417 A1
(43) Pub. Date: Mar. 4, 2021

(54) Display Substrate and Preparation Method thereof, and Display Apparatus

(71) Applicants: Hefei Xinsheng Optoelectronics Technology Co., Ltd., Hefei (CN); BOE Technology Group Co., Ltd., Beijing (CN)

(72) Inventors: Xinzhu WANG, Beijing (CN); Fei LI, Beijing (CN); Huihui LI, Beijing (CN); Xinfeng WU, Beijing (CN); Youyuan HU, Beijing (CN)

(21) Appl. No.: 16/914,487

(22) Filed: Jun. 29, 2020

(30) Foreign Application Priority Data
Aug. 29, 2019 (CN) 201910820689.5

(51) Int. Cl. H01L 27/32

(52) U.S. Cl. CPC H01L 27/3246; H01L 2227/323

(57) ABSTRACT

Provided are a display substrate and a preparation method thereof, and a display apparatus. The display substrate has a pixel definition layer and a light emitting layer disposed on a driving circuit layer; wherein the light emitting layer is configured to emit light, an isolation layer is disposed between the pixel definition layer and the light emitting layer, and the isolation layer is configured to prevent vapor and oxygen from entering the light emitting layer.

### CROSS-REFERENCE TO RELATED APPLICATION

The present application claims the priority of Chinese Patent Application No. 201910820689.5 filed to CNIPA on Aug. 29, 2019, the content of which is hereby incorporated by reference.

### TECHNICAL FIELD

The present disclosure relates to, but is not limited to the technical field of display, specifically to a display substrate and a preparation method thereof, and a display apparatus.

### BACKGROUND

Organic Light Emitting Diode (OLED) display apparatus has advantages such as active light emission, ultra-thin, wide viewing angle, high contrast, high brightness, high response speed, low driving voltage and flexible display, etc., and has gradually become a next generation display technology with a great development prospect. According to different driving modes, OLED may be divided into two types, Passive Matrix (PM) driving type and Active Matrix (AM) driving type. AMOLED is a current driving device, and use an independent Thin Film Transistor (TFT) to control each sub-pixel, wherein each sub-pixel may continuously and independently drive light emission.

### SUMMARY

The following is a summary of the subject matter described in detail herein. This summary is not intended to limit the protection scope of the claims.

A display substrate includes a pixel definition layer and a light emitting layer which are arranged on a driving circuit layer, wherein the light emitting layer is configured to emit light, an isolation layer is disposed between the pixel definition layer and the light emitting layer, and the isolation layer is configured to prevent vapor and oxygen from entering the light emitting layer.

In some possible implementations, the driving circuit layer includes a first electrode; the pixel defining layer is disposed on the driving circuit layer, and a first opening exposing the first electrode is disposed on the pixel defining layer; the isolation layer is disposed on the pixel definition layer, and a second opening corresponding to the first opening is disposed on the isolation layer, wherein the second opening only exposes the first electrode; the light emitting layer is disposed on the isolation layer, and is connected with the first electrode exposed by the second opening.

In some possible implementations, an orthographic projection of the second opening on the driving circuit layer is within an orthographic projection range of the first opening on the driving circuit layer.

In some possible implementations, an equivalent diameter of the second opening=(0.85˜0.95)*an equivalent diameter of the first opening.

In some possible implementations, a material of the isolation layer includes any one or more of following: silicon oxide and silicon nitride.

The present disclosure also provides a display apparatus, including the above display substrate.

A method for preparing a display substrate includes: forming a pixel definition layer on a driving circuit layer; forming an isolation layer on the pixel definition layer, wherein the isolation layer is configured to prevent vapor and oxygen from entering the light emitting layer; forming a light emitting layer on the isolation layer, wherein the light emitting layer is configured to emit light.

In some possible implementations, forming the pixel definition layer on the driving circuit layer, includes: forming, on a substrate, the driving circuit layer including a first electrode; forming the pixel definition layer on the driving circuit layer, wherein a first opening corresponding to a light emitting region is formed on the pixel definition layer, and the first opening exposes the first electrode.

In some possible implementations, forming the isolation layer on the pixel definition layer, includes: depositing a layer of isolation thin film; patterning the isolation thin film through a patterning process to form the isolation layer, wherein a second opening corresponding to the first opening is formed on the isolation layer, and the first electrode is exposed within the second opening.

In some possible implementations, forming the pixel definition layer on the driving circuit layer, includes: forming the driving circuit layer including the first electrode on the substrate; a pixel definition layer and a pixel protection layer are formed on the driving circuit layer, wherein a first opening corresponding to a light emitting region is formed on the pixel definition layer, the pixel protection layer is formed within the first opening, and a region between the pixel definition layer and the pixel protection layer exposes the first electrode.

In some possible implementations, forming the isolation layer on the pixel definition layer, includes: depositing a layer of isolation thin film; patterning the isolation thin film through a patterning process, etching away the isolation thin film on top of the pixel protection layer to expose the pixel protection layer; removing, through a stripping process, the pixel protection layer, and the isolation thin film on the pixel protection layer, to form a pattern of the isolation layer, wherein a second opening corresponding to the first opening is formed on the isolation layer, and the second opening only exposes the first electrode.

In some possible implementations, an orthographic projection of the second opening on the driving circuit layer is within an orthographic projection range of the first opening on the driving circuit layer.

In some possible implementations, an equivalent diameter of the second opening=(0.85˜0.95)*an equivalent diameter of the first opening.

In some possible implementations, a material of the isolation layer includes any one or more of following: silicon oxide and silicon nitride.

Other aspects will become apparent upon reading and understanding the drawings and the detailed description.

### BRIEF DESCRIPTION OF DRAWINGS

Accompanying drawings are used for providing a further understanding of technical solutions of the present disclosure and form a part of the specification. Together with embodiments of the present application, the accompanying drawings are used for explaining technical solutions of the present disclosure, and do not constitute a limitation on the technical solutions of the present disclosure. Shapes and sizes of various components in the accompanying drawings do not reflect real proportions, and are only for a purpose of schematically illustrating contents of the present disclosure.

FIG. 1 is a schematic diagram of structure of a display substrate according to the present disclosure.

FIG. 2 is a schematic diagram of structure after a pattern of a driving circuit layer is formed according to the present disclosure.

FIG. 3 is a schematic diagram of structure after a pattern of a flat layer is formed according to the present disclosure.

FIG. 4 is a schematic diagram of structure after a pattern of a first electrode is formed according to the present disclosure.

FIG. 5 is a schematic diagram of structure after a pattern of a pixel definition layer is formed according to the present disclosure.

FIG. 6 is a schematic diagram of structure after a pattern of an isolation layer is formed according to the present disclosure.

FIG. 7 is a schematic diagram of structure after patterns of a pixel definition layer and a pixel protection layer are formed according to the present disclosure.

FIG. 8 is a schematic diagram of structure after an isolation thin film is deposited according to the present disclosure.

FIG. 9 is a schematic diagram of structure after an isolation thin film is etched according to the present disclosure.

FIG. 10 is a schematic diagram of structure after a pattern of an isolation layer is formed according to the present disclosure.

### DESCRIPTION OF THE REFERENCE SIGNS

10—Substrate; 11—Driving layer; 12—Thin film transistor; 13—Insulation layer; 14—First electrode; 15—Pixel definition layer; 16—Isolation layer; 17—Light emitting layer; 18—Second electrode; 19—Pixel protection layer.

### DETAILED DESCRIPTION

Embodiments herein may be implemented in multiple different forms. One of ordinary skill in the technical field may easily understand a fact that an implementation and a content may be changed into various forms under a condition of not departing from an aim of the present disclosure and a scope thereof. Therefore, the present disclosure should not be construed as limited only to what is recorded in following embodiments. Without conflict, embodiments in the present disclosure and features in the embodiments may be combined with each other arbitrarily.

With development of a high resolution (PPI) display technology, pixels are becoming more and more refined, not only a pixel size is getting smaller and smaller, but also spacing between pixels is getting smaller and smaller, which is easy to cause light leakage between pixels. In order to prevent light leakage between pixels, a display substrate uses a Pixel Definition Layer (PDL) to block light leakage between pixels, but there is a problem of pixel shrinkage, which seriously affects product yield. It is found by research that pixel shrinkage is caused by vapor and oxygen from the Pixel Definition Layer. In a display substrate, an anode is prepared on a flat layer, then a pixel definition layer with an opening is prepared, and then a light emitting layer is formed on the pixel definition layer and within the opening, and the light emitting layer is configured to emit light. Therefore, a light emitting layer and a pixel definition layer in a display substrate are in direct contact. The pixel definition layer is of an organic material. In a subsequent lighting process of the light emitting layer, the pixel definition layer will separate out gas such as vapor (water vapor etc.) and dissolved oxygen under an action of a certain environmental factor such as temperature and pressure. As the pixel definition layer is in direct contact with the light emitting layer, the gas such as vapor and oxygen separated out by the pixel definition layer directly enters into the light emitting layer, and the light emitting material will quickly fail after reacting with the vapor and oxygen, thus a problem of pixel shrinkage appears. A main reflection of pixel shrinkage is that periphery of pixels is dark, which will lead to a defect such as color shift and dark spots in a picture in a serious case, seriously affecting product yield and service life. It is found by further research that, it is not only with a large difficulty but also with an unsatisfactory effect to eliminate, by controlling a material of the pixel definition layer or preparation process parameters, the separation of vapor and oxygen from the pixel definition layer. In actual production, even slight changes in the material of the pixel definition layer or an OLED preparation process flow will lead to a substantial increase in a defect rate of Reliant Appraise (RA) test, and even the defect rate of the Reliant Appraise test caused by the entering of vapor and oxygen into the light emitting layer may reach 100%.

The present disclosure provides a display substrate, including: a pixel definition layer and a light emitting layer which are arranged on a driving circuit layer, wherein the light emitting layer is configured to emit light, an isolation layer is disposed between the pixel definition layer and the light emitting layer, and the isolation layer is configured to prevent vapor and oxygen from entering the light emitting layer.

In an exemplary embodiment, the driving circuit layer is disposed on a substrate, the driving circuit layer includes a thin film transistor and a first electrode connected to a drain electrode of the thin film transistor, the pixel definition layer is disposed on the driving circuit layer, a first opening corresponding to a light emitting region is disposed on the pixel definition layer, and the first electrode is exposed within the first opening. An isolation layer is disposed on the pixel definition layer, a second opening corresponding to the first opening is disposed on the isolation layer, and only the first electrode is exposed within the second opening. The light emitting layer is disposed on the isolation layer, and is connected with the first electrode exposed within the second opening.

In an exemplary embodiment, an area of the second opening is smaller than an area of the first opening, that is, an orthographic projection of the second opening on the substrate (the driving circuit layer) is located within an orthographic projection range of the first opening on the substrate (the driving circuit layer). In an exemplary embodiment of the present disclosure, “an orthographic projection of A is located in an orthographic projection of B” means that a boundary of the orthographic projection of A falls within a boundary range of the orthographic projection of B, or a boundary of the orthographic projection of A overlaps with a boundary of the orthographic projection of B.

FIG. 1 is a schematic diagram of structure of a display substrate according to the present disclosure, illustrating a bottom emission display substrate structure. As shown in FIG. 1, in an exemplary embodiment, the display substrate includes: a substrate 10; a driving layer 11 disposed on the substrate 10, the driving layer 11 including a thin film transistor 12 having a top gate structure; an insulating layer 13 covering the driving layer 11, a first via hole exposing a drain electrode of the thin film transistor 12 being disposed on the insulating layer 13; a first electrode 14 disposed on the insulating layer 13, the first electrode 14 being connected to the drain electrode of the thin film transistor 12 through the first via hole; a pixel definition layer 15 provided on the insulating layer 13 and the first electrode 14, a first opening corresponding to a light emitting region being disposed on the pixel definition layer 15, and the first opening exposing the first electrode 14; an isolation layer 16 disposed on the pixel definition layer 15, a second opening corresponding to the first opening being disposed on the isolation layer 16, and an area of the second opening being smaller than an area of the first opening, to make that only the first electrode 14 is exposed within the second opening; a light emitting layer 17 disposed on the isolation layer 16, the light emitting layer 17 being connected to the first electrode 14 exposed within the second opening; a second electrode 18 disposed on the light emitting layer 17, the second electrode 18 being connected to the light emitting layer 17.

Herein, an orthographic projection of the second opening on the substrate is within an orthographic projection range of the first opening on the substrate.

In an exemplary embodiment, an equivalent diameter of the second opening=(0.85˜0.95)*an equivalent diameter of the first opening.

In an exemplary embodiment, the driving layer 11, the insulating layer 13 and the first electrode 14 together constitute a driving circuit layer. The isolation layer 16 may include any one or more of following: Silicon Oxide (SiOx) and Silicon Nitride (SiNx), and the isolation layer 16 may be a single layer, or multiple layers, or a composite layer including SiOx and SiNx. In some possible implementations, the isolation layer 16 is referred to as a passivation layer. The material of the insulating layer 13 may include any one or more of following: polysiloxane-based materials, acrylic-based materials, and polyimide-based materials. In some possible implementations, the insulating layer 13 is referred to as a flat (PLN) layer. For a bottom emission structure, the first electrode may be a transparent anode and the second electrode may be a reflective cathode. For a top emission structure, the first electrode may be a reflective anode and the second electrode may be a transparent cathode.

According to the present disclosure, an isolation layer is disposed on a pixel definition layer, so that a light emitting layer and the pixel definition layer are isolated from each other, gas such as vapor and oxygen separated out by the pixel definition layer is prevented or reduced from entering the light emitting layer, damage of the vapor and oxygen to the light emitting layer is eliminated, and occurrence of a pixel shrinkage phenomenon is avoided, which may not only greatly improve yield of Reliant Appraise test, but also may greatly improve reliability and life of OLED.

In an exemplary embodiment, a technical solution of the present disclosure is applicable to the top emission display substrate structure. In some possible implementations, the display substrate of the present disclosure may include another structural layer, such as an encapsulating layer, a light shielding layer, etc., and the thin film transistor in the driving layer may be a top gate structure, or may be a bottom gate structure, which is not limited here in the present disclosure.

The present disclosure further provides a display apparatus, including the aforementioned display substrate. The display apparatus may include any one or more of following: any product or component with a display function such as a mobile phone, a tablet computer, a television, a display, a notebook computer, a digital photo frame, a navigator, etc.

The present disclosure also provides a method for preparing a display substrate, and the display substrate shown in FIG. 1 may be prepared.

In an exemplary embodiment, the method for preparing the display substrate may include the following acts. In S1, a pixel definition layer is formed on a driving circuit layer. In S2, an isolation layer is formed on the pixel definition layer, the isolation layer being configured to prevent vapor and oxygen from entering the light emitting layer. In S3, a light emitting layer is formed on the isolation layer, the light emitting layer being configured to emit light.

According to the present disclosure, an isolation layer is formed on a pixel definition layer, so that a light emitting layer and the pixel definition layer are isolated from each other, gas such as vapor and oxygen separated out by the pixel definition layer is prevented or reduced from entering the light emitting layer, damage of the vapor and oxygen to the light emitting layer is eliminated, and occurrence of a pixel shrinkage phenomenon is avoided, which may not only greatly improve yield of Reliant Appraise test, but also may greatly improve reliability and life of OLED.

In an exemplary embodiment, act S1 may include the following acts. In S111, the driving circuit layer including a first electrode is formed on a substrate. In S112, the pixel definition layer is formed, a first opening corresponding to a light emitting region being formed on the pixel definition layer, and the first opening exposing the first electrode.

In some possible implementations, act S111 may include: forming a driving layer on the substrate, the driving layer including a thin film transistor; forming a flat layer on the driving layer, a first via hole exposing a drain electrode of the thin film transistor being formed on the flat layer; forming the first electrode on the flat layer, the first electrode being connected with the drain electrode of the thin film transistor through the first via hole.

In an exemplary embodiment, act S2 may include: S211, a layer of isolation thin film is deposited; S212, the isolation thin film is patterned through a patterning process to form the isolation layer, a second opening corresponding to a first opening being formed on the isolation layer, and only the first electrode being exposed within the second opening.

In some possible implementations, an orthographic projection of the second opening on the substrate is within an orthographic projection range of the first opening on the substrate.

In some possible implementations, an area of the second opening is smaller than an area of the first opening K1, and an equivalent diameter of the second opening=(0.85˜0.95)*an equivalent diameter of the first opening.

In some possible implementations, the material of the isolation layer may include any one or more of following: Silicon Oxide (SiOx) and Silicon Nitride (SiNx), and may be etched by a dry etching method.

In an exemplary embodiment, act S3 may include: S311, a light emitting layer is formed on the isolation layer, the light emitting layer being connected to the first electrode exposed by the second opening; S312, a second electrode is formed, the second electrode being connected to the light emitting layer.

A process for preparing a display substrate is described below for illustration. The “patterning process” mentioned in the present disclosure includes processes, such as deposition film layer, coating photoresist, mask exposure, development, etching, and stripping photoresist, etc. Any one or more of sputtering, evaporation and chemical vapor deposition may be used for deposition, any one or more of spraying and spin coating may be used for coating, and any one or more of dry etching and wet etching may be used for etching, which is not limited in the present disclosure. “Thin film” refers to a layer of thin film fabricated by taking a certain material on a base substrate using deposition or another process. If the “thin film” does not need a patterning process throughout the fabrication process, the “thin film” may also be referred to as a “layer”. If the “thin film” needs a patterning process throughout the fabrication process, it is referred to as a “thin film” before the patterning process and as a “layer” after the patterning process. The “layer” which has undergone a patterning process contains at least one “pattern”.

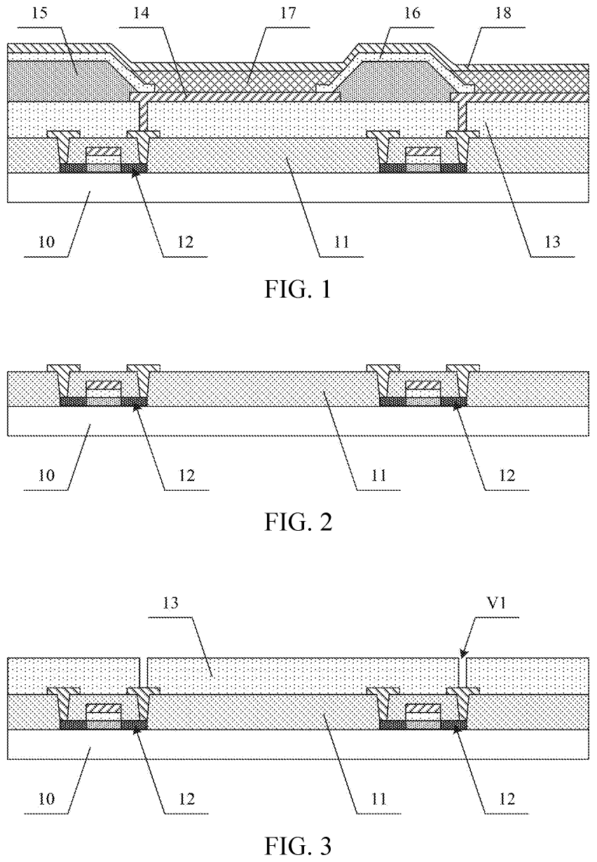

(1) A pattern of a driving layer is formed. In an exemplary embodiment, a driving layer 11 is formed on a substrate 10, and a thin film transistor 12 is included, as shown in FIG. 2. In some possible implementations, the driving layer may include patterns of an active layer, a gate electrode, a source electrode, and a drain electrode formed sequentially. As an example, the process of forming the pattern of the driving layer may include A, B, C and D.

A, an Active thin film is deposited on a substrate, and the Active thin film is patterned through a patterning process to form a pattern of an active layer.

B, a first insulating thin film and a first metal thin film are sequentially deposited on the substrate on which the aforementioned pattern is formed, the first insulating thin film and the first metal thin film are patterned through a patterning process, and patterns of a first insulating layer and a gate electrode are formed on an active layer; subsequently, exposed regions on both sides of the active layer are conductively treated by using the pattern of the gate electrode as a shield to make doped regions be formed on both sides of the active layer. In an exemplary embodiment, the first insulating layer is referred to as a Gate Insulating (GI) layer.

C, a second insulating thin film is deposited on the substrate on which the aforementioned patterns are formed, and the second insulating thin film is patterned through a patterning process to form a second insulating layer covering the gate electrode, two via holes being opened on the second insulating layer, and the second insulating layer in the two via holes being etched away to expose the doped regions on both sides of the active layer. In an exemplary embodiment, the second insulating layer is referred to as an Interlayer Insulating (ILD) layer.

D, a second metal thin film is deposited on the substrate on which the aforementioned patterns are formed, the second metal thin film is patterned through a patterning process, and a source electrode and a drain electrode are formed on the second insulating layer, the source electrode being connected with the doped region on one side of the active layer through one via hole, and the drain electrode being connected with the doped region on the other side of the active layer through the other via hole.

Thus, the driving layer 11 including the thin film transistor 12 is formed on the substrate 10. In an exemplary embodiment, the first and second metal thin films may be made of a metal material, such as silver (Ag), copper (Cu), aluminum (Al), molybdenum (Mo), or the like, or alloy materials of the above metals, such as aluminum niobium alloy (AlNd) or molybdenum niobium alloy (MoNb), or the like, may be a single-layer structure, or a multi-layer composite structure, such as Mo/Cu/Mo, or the like, or may be a stack structure formed of metal and transparent conductive materials, such as ITO/Ag/ITO, or the like. The active layer thin film may use various materials such as amorphous indium gallium zinc Oxide (a-IGZO), zinc oxynitride (ZnON), indium zinc tin oxide (IZTO), amorphous silicon (a-Si), polysilicon (p-Si), hexathiophene, polythiophene, or the like, that is, the present disclosure is applicable to thin film transistors manufactured based on an Oxide technology, a silicon technology and an organic technology. The first and second insulating thin films may use any one or more of silicon oxide (SiOx), silicon nitride (SiNx) and silicon oxynitride (SiON), or may use a high dielectric constant (High k) material such as aluminum oxide (AlOx), hafnium oxide (HfOx), tantalum oxide (TaOx), or the like, and may be a single layer, multiple layers, or a composite layer. In some possible implementations, a buffer layer may be formed on the substrate first, and then an active layer is formed on the buffer layer.

(2) A pattern of a flat layer is formed. In an exemplary embodiment, forming the pattern of the flat layer may include: coating a flat thin film on the substrate on which the aforementioned patterns are formed to form a pattern of a flat layer 13 covering a driving layer 11 through masking, exposure and development, a first via hole V1 being formed on the flat layer 13, the first via hole V1 being located at a drain electrode position of a thin film transistor 12, and the flat layer 13 within the first via hole V1 being removed to expose a surface of a drain electrode of the thin film transistor 12, as shown in FIG. 3. In some possible implementations, the material of the flat thin film includes, but is not limited to, any one or more of following: polysiloxane-based materials, acrylic-based materials, and/or polyimide-based materials.

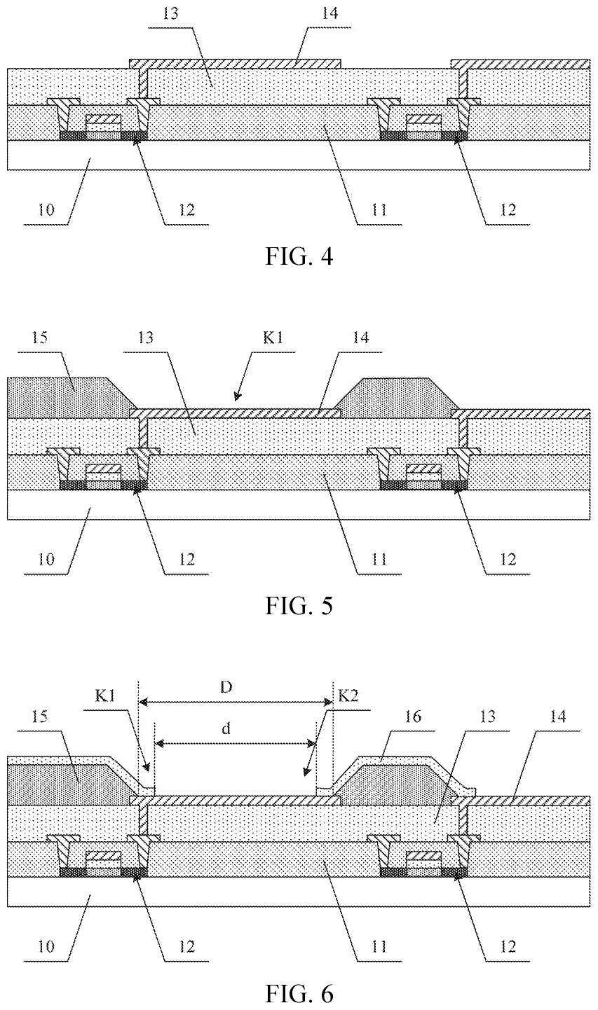

(3) A pattern of a first electrode is formed. In an exemplary embodiment, forming the pattern of the first electrode includes: depositing a transparent conductive thin film on the substrate on which the aforementioned patterns are formed, and patterning the transparent conductive thin film through a patterning process to form a pattern of a first electrode 14, the first electrode 14 being connected with a drain electrode of a thin film transistor 12 through a first via hole V1, as shown in FIG. 4. In some possible implementations, for a bottom emission structure, the first electrode is a transparent anode, and the material of the first electrode may use any one or more of following: indium tin oxide ITO and indium zinc oxide IZO.

(4) A pattern of a pixel definition layer is formed. In an exemplary embodiment, forming the pattern of the pixel definition layer includes: coating a pixel definition thin film on the substrate on which the aforementioned patterns are formed, and forming a pattern of a pixel definition layer 15 on a flat layer 13 through masking, exposure and development, a first opening K1 being formed on the pixel definition layer 15, a position of the first opening K1 corresponding to a light emitting region, and the first opening K1 exposing a surface of a first electrode 14, as shown in FIG. 5.

(5) A pattern of an isolation layer is formed. In an exemplary embodiment, forming the pattern of the isolation layer includes: depositing an isolation thin film covering an entire substrate on the substrate on which the aforementioned patterns are formed, and patterning the isolation thin film through a patterning process to form a pattern of an isolation layer 16, a second opening K2 corresponding to a first opening K1 being formed on the isolation layer 16, and the second opening K2 only exposing a surface of a first electrode 14, as shown in FIG. 6.

In an exemplary embodiment, the second opening K2 is opened within a range of the first opening K1, an isolation layer 16 in a middle region within the first opening K1 is etched away, while the isolation layer 16 in an edge region within the first opening K1 and the isolation layer 16 covering the pixel definition layer 15 are retained. That is, an area of the second opening K2 is smaller than an area of the first opening K1, and an orthographic projection of the second opening K2 on the substrate is within an orthographic projection range of the first opening K1 on the substrate. As shown in FIG. 6, an equivalent diameter of the first opening K1 is D, and an equivalent diameter of the second opening K2 is d, d<D. In some possible implementations, d=(0.85˜0.95) D is set to ensure an aperture ratio. In this way, the formed isolation layer 16 not only completely covers the pixel definition layer 15, but also covers an edge region of the first opening K1 adjacent to the pixel definition layer 15, that is, an edge region of the first electrode 14 adjacent to the pixel definition layer 15 is covered by the isolation layer 16. In this way, it may be caused that the light emitting layer will not come into contact with the pixel definition layer 15, when the light emitting layer is subsequently formed. In some possible implementations, the isolation layer 16 may use any one or more of following: Silicon Oxide (SiOx) and Silicon Nitride (SiNx), may be a single layer, or may be multiple layers, or may be a composite layer containing SiOx and SiNx, and may be etched by a dry etching method.

(6) Patterns of a light emitting layer and a second electrode are formed. In an exemplary embodiment, forming the patterns of the light emitting layer and the second electrode includes: preparing sequentially patterns of a light emitting layer 17 and a second electrode 18 by using a mode of vapor deposition or ink jet printing on the substrate on which the aforementioned patterns are formed. The light emitting layer 17 is formed in an isolation layer 16 and within a second opening K2 opened in the isolation layer 16, and is connected with a first electrode 14 exposed within the second opening K2. The second electrode 18 is formed on the light emitting layer 17 and is connected with the light emitting layer 17 as shown in FIG. 1. In some possible implementations, for the bottom emission structure, the second electrode is a reflective cathode, and a material of the second electrode may be a metal material and may be prepared using a mode of vapor deposition.

A subsequent preparation process includes formation of a structure such as an encapsulation layer, or the like, which will not be repeated here.

Since the isolation layer covering the pixel definition layer is formed first and then the light emitting layer is manufactured, the isolation of the light emitting layer and the pixel definition layer from each other is realized by using the isolation layer. Even if the pixel definition layer separates out gas such as vapor and oxygen in a subsequent lighting process of the light emitting layer, since the isolation layer isolates the vapor and oxygen from entering a transmission channel of the light emitting layer, vapor and oxygen separated out by the pixel definition layer is prevented or reduced from entering the light emitting layer, damage of the vapor and oxygen to the light emitting layer is eliminated, and occurrence of a pixel shrinkage phenomenon is avoided, which may not only greatly improve yield of Reliant Appraise test, and improve product yield, but also may greatly improve reliability and life of OLED.

Since the material of the flat layer is also an organic material, a situation of vapor and oxygen also exists for the flat layer. In a display substrate, since a flat layer is in direct contact with a pixel definition layer, and the pixel definition layer is in direct contact with a light emitting layer, gas such as vapor and oxygen separated out by the flat layer will also enter the light emitting layer. According to the present disclosure, by disposing an isolation layer which isolates a light emitting layer and a pixel definition layer from each other, a transmission channel by which vapor and oxygen enters the light emitting layer is cut off, so that the vapor and oxygen of the flat layer cannot enter the light emitting layer, either, eliminating damage of the vapor and oxygen to the light emitting layer, and avoiding occurrence of a pixel shrinkage phenomenon.

According to the present disclosure, preparation of a display substrate does not need to change an existing process flow or an existing process equipment, having good process compatibility, high process realizability, strong practicability, simple method and obvious effect.

In another exemplary embodiment, act S1 may include: S121, a driving circuit layer including a first electrode is formed on a substrate; S122, a pixel definition layer and a pixel protection layer are formed, wherein a first opening corresponding to a light emitting region is formed on the pixel definition layer, the pixel protection layer is formed within the first opening, and a region between the pixel definition layer and the pixel protection layer exposes the first electrode.

In some possible implementations, act S121 and the aforementioned act S111 are same.

In an exemplary embodiment, act S2 may include the following acts. In S221, an isolation thin film is deposited. In S222, the isolation thin film is patterned through a patterning process, an isolation thin film on top of the pixel protection layer being etched away to expose the pixel protection layer. In S223, the pixel protection layer and the isolation thin film on the pixel protection layer are removed through a stripping process, to form a pattern of the isolation layer, a second opening corresponding to a first opening being formed on the isolation layer, and only the first electrode being exposed within the second opening.

In some possible implementations, an orthographic projection of the second opening on the substrate is within an orthographic projection range of the first opening on the substrate.

In some possible implementations, an area of the second opening is smaller than an area of the first opening K1, and an equivalent diameter of the second opening=(0.85˜0.95)*an equivalent diameter of the first opening.

In some possible implementations, a material of the isolation layer may include any one or more of following: Silicon Oxide (SiOx) and Silicon Nitride (SiNx), and may be etched by a dry etching method.

In some possible implementations, act S3 and the aforementioned acts S311 and S312 are same.

A preparation process of the display substrate is described below for illustration.

(1) In an exemplary embodiment, a process of forming the driving layer, the flat layer, and the pattern of the first electrode may be same as the aforementioned process.

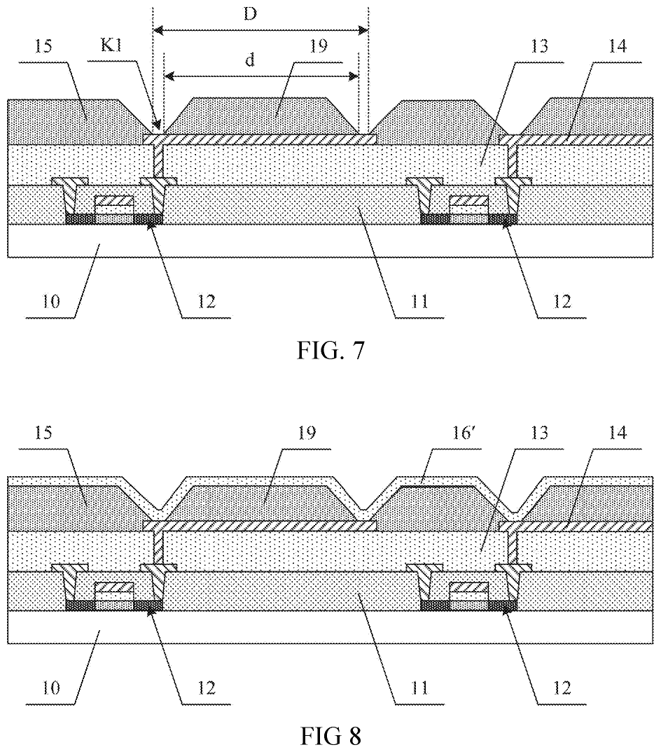

(2) Patterns of a pixel definition layer and a pixel protection layer are formed. In an exemplary embodiment, forming the patterns of the pixel definition layer and the pixel protection layer may include: coating a layer of pixel definition thin film on a substrate formed with the aforementioned patterns, and forming the patterns of the pixel definition layer 15 and the pixel protection layer 19 through masking, exposure and development, a first opening K1 being formed on the pixel definition layer 15, a position of the first opening K1 corresponding to a light emitting region, the pixel protection layer 19 being formed within the first opening K1, and a region between the pixel definition layer 15 and the pixel protection layer 19 exposing a surface of the first electrode 14, as shown in FIG. 7.

In an exemplary embodiment, in order to avoid damaging the surface of the first electrode during a subsequent process of etching the isolation layer, a pattern of the pixel protection layer 19 is introduced. The pixel protection layer 19 is disposed on the first electrode 14 to realize protection on the first electrode 14. The pixel protection layer 19 is formed within a range of the first opening K1, and for the first electrode 14 exposed by the first opening K1, a middle region is covered by the pixel protection layer 19, and an edge region is exposed. That is, an area occupied by the pixel protection layer 19 is smaller than an area exposed by the first opening K1, and an orthographic projection of the pixel protection layer 19 on the substrate is within an orthographic projection range of the first opening K1 on the substrate. In an exemplary embodiment, a cross-sectional shape of the pixel protection layer 19 may be trapezoidal, an equivalent diameter of the first opening K1 is D, and an equivalent diameter of a lower bottom of the pixel protection layer 19 is d, d<D. In some possible implementations, d=(0.85˜0.95) D is set to ensure an aperture ratio.

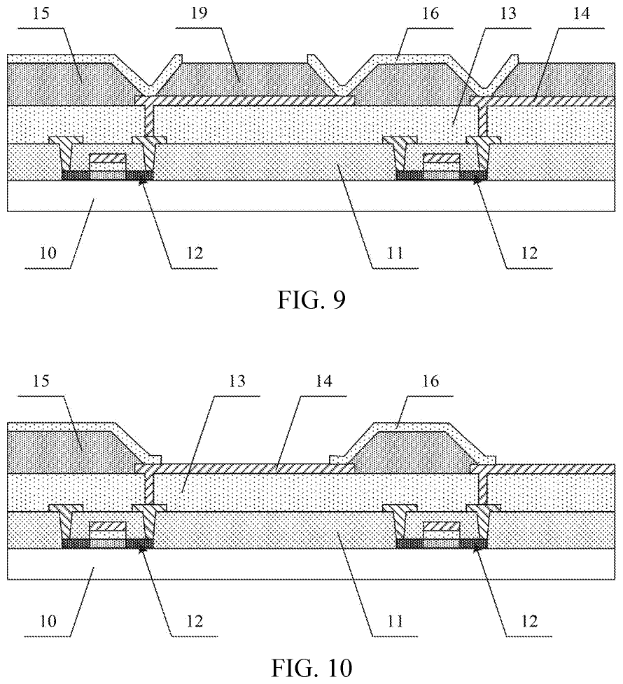

(3) A pattern of an isolation layer is formed. In an exemplary embodiment, forming the pattern of the isolation layer may include: depositing a layer of isolation thin film 16′ covering the entire substrate on a substrate formed with the aforementioned patterns, as shown in FIG. 8. Subsequently, the isolation thin film 16′ is patterned by a patterning process, and the isolation thin film 16′ located on an upper bottom (top) of the pixel protection layer 19 is etched away to expose the pixel protection layer 19, as shown in FIG. 9. Finally, the pixel protection layer 19 is removed by a stripping process, and the isolation thin films 16′ on both side walls of the pixel protection layer 19 will be removed together with the pixel protection layer 19 to form a pattern of an isolation layer 16. A second opening K2 corresponding to a first opening K1 is formed on the isolation layer 16, and only a surface of the first electrode 14 is exposed within the second opening K2, as shown in FIG. 10. In an exemplary embodiment, a relevant parameter of the second opening K2 and that of the aforementioned second opening K2 are same. In this way, the formed isolation layer 16 not only completely covers the pixel definition layer 15, but also covers an edge region of the first opening K1, that is, an edge region of the first electrode 14 adjacent to the pixel definition layer 15 is covered by the isolation layer 16.

(4) Patterns of a light emitting layer, a second electrode and an encapsulating layer are formed. The process of forming the light emitting layer, the second electrode and the encapsulation layer may be same as the aforementioned process.

The present disclosure realizes that a light emitting layer and a pixel definition layer are isolated from each other by using an isolation layer, which prevents or alleviates gas such as vapor and oxygen, or the like separated out by the pixel definition layer and a flat layer from entering the light emitting layer, eliminates damage of vapor and oxygen to the light emitting layer, and avoids occurrence of a pixel shrinkage phenomenon. By disposing a pixel protection layer, damage to a first electrode in a process of etching the isolation layer is avoided, performance of a light emitting structure is ensured, and display quality is ensured. According to the present disclosure, preparation of a display substrate does not need to change a process flow or a process equipment, having good process compatibility, high process reliability, strong practicability, simple method and obvious effect.

In the description of the present disclosure, it should be understood that azimuth or positional relationships indicated by terms “middle”, “upper”, “lower”, “front”, “rear”, “vertical”, “horizontal”, “top”, “bottom”, “inside”, “outside”, or the like is based on azimuth or positional relationship shown in the drawings, which is only for ease of description of the present disclosure and simplification of the description, rather than indicating or implying that the apparatus or the element referred to must have a specific orientation, or must be constructed and operated in a particular orientation, and therefore cannot be construed as limiting the present disclosure.

In the description of the present disclosure, it need be noted that terms “installed”, “connected” and “connected” shall be broadly understood unless otherwise explicitly specified and defined, for example, it may be fixedly connected, or may be removably connected, or may be integrally connected; it may be mechanically connected, or may be electrically connected; it may be directly connected, or may be indirectly connected through an intermediate medium, or it may be internal connection between two elements. Those of ordinary skill in the art may understand the specific meanings of the above terms in the present disclosure according to a specific situation.

Although embodiments disclosed in the present disclosure are as the above, the contents are only embodiments for facilitating understanding the present disclosure, rather than restricting the present disclosure. Any person skilled in the art to which the present disclosure pertains may make any modifications and variations in forms and details of implementation, without departing from the spirit and the scope disclosed by the present disclosure. However, the protection scope of claims of the present application shall still be subject to the scope defined in the appended claims.

What is claimed is:

1. A display substrate, comprising a pixel definition layer and a light emitting layer disposed on a driving circuit layer; wherein the light emitting layer is configured to emit light, an isolation layer is disposed between the pixel definition layer and the light emitting layer, and the isolation layer is configured to prevent vapor and oxygen from entering the light emitting layer.

2. The display substrate according to claim 1, wherein the driving circuit layer comprises a first electrode; the pixel defining layer is disposed on the driving circuit layer, and a first opening exposing the first electrode is disposed on the pixel defining layer; the isolation layer is disposed on the pixel definition layer, and a second opening corresponding to the first opening is disposed on the isolation layer, wherein the second opening exposes only the first electrode; the light emitting layer is disposed on the isolation layer, and is connected with the first electrode exposed by the second opening.

3. The display substrate according to claim 2, wherein an orthographic projection of the second opening on the driving circuit layer is within an orthographic projection range of the first opening on the driving circuit layer.

4. The display substrate according to claim 2, wherein an equivalent diameter of the second opening=(0.85˜0.95)*an equivalent diameter of the first opening.

5. The display substrate according to claim 1, wherein a material of the isolation layer comprises any one or more of following: silicon oxide and silicon nitride.

6. A display apparatus, having the display substrate according to claim 1.

7. A method for preparing a display substrate, comprising:
forming a pixel definition layer on a driving circuit layer;
forming an isolation layer on the pixel definition layer, wherein the isolation layer is configured to prevent vapor and oxygen from entering an light emitting layer; and
forming the light emitting layer on the isolation layer, wherein the light emitting layer is configured to emit light.

8. The method for preparing the display substrate according to claim 7, wherein forming the pixel definition layer on the driving circuit layer, comprises:
forming, on a substrate, the driving circuit layer comprising a first electrode; and
forming the pixel definition layer on the driving circuit layer, wherein a first opening corresponding to a light emitting region is formed on the pixel definition layer, and the first opening exposes the first electrode.

9. The method for preparing the display substrate according to claim 8, wherein forming, on the substrate, the driving circuit layer comprising the first electrode, comprises:
forming a driving layer on the substrate, wherein the driving layer comprises a thin film transistor;
forming a flat layer on the driving layer, wherein a first via hole exposing a drain electrode of the thin film transistor is formed on the flat layer; and
forming the first electrode on the flat layer, wherein the first electrode is connected with the drain electrode of the thin film transistor through the first via hole.

10. The method for preparing the display substrate according to claim 8, wherein forming the isolation layer on the pixel definition layer comprises:
depositing a layer of isolation thin film; and
patterning the isolation thin film through a patterning process to form the isolation layer, wherein a second opening corresponding to the first opening is formed on the isolation layer, and the first electrode is exposed within the second opening.

11. The method for preparing the display substrate according to claim 7, wherein forming the pixel definition layer on the driving circuit layer comprises:
forming, on a substrate, the driving circuit layer comprising a first electrode; and
forming a pixel definition layer and a pixel protection layer on the driving circuit layer, wherein a first opening corresponding to a light emitting region is formed on the pixel definition layer, the pixel protection layer is formed within the first opening, and a region between the pixel definition layer and the pixel protection layer exposes the first electrode.

12. The method for preparing the display substrate according to claim 11, wherein forming the isolation layer on the pixel definition layer comprises:
depositing a layer of isolation thin film;
patterning the isolation thin film through a patterning process, etching away the isolation thin film on top of the pixel protection layer to expose the pixel protection layer; and
removing, through a stripping process, the pixel protection layer and the isolation thin film on the pixel protection layer, to form the isolation layer, wherein a second opening corresponding to the first opening is formed on the isolation layer, and the second opening exposes only the first electrode.

13. The method for preparing the display substrate according to claim 10, wherein an orthographic projection of the second opening on the driving circuit layer is within an orthographic projection range of the first opening on the driving circuit layer.

14. The method for preparing the display substrate according to claim 10, wherein an equivalent diameter of the second opening=(0.85˜0.95)*an equivalent diameter of the first opening.

15. The method for preparing the display substrate according to claim 12, wherein an orthographic projection of the second opening on the driving circuit layer is within an orthographic projection range of the first opening on the driving circuit layer.

16. The method for preparing the display substrate according to claim 12, wherein an equivalent diameter of the second opening=(0.85˜0.95)*an equivalent diameter of the first opening.

17. The method for preparing the display substrate according to claim 7, wherein a material of the isolation layer comprises any one or more of following: silicon oxide and silicon nitride.
